(19) United States
(12) Patent Application Publication
(10) Pub. No.: US 2012/0177844 A1
(43) Pub. Date: Jul. 12, 2012

(54) METHOD AND DEVICE FOR CHEMICAL VAPOR DEPOSITION OF POLYMER FILM ONTO A SUBSTRATE

(75) Inventors: Claudine Biver, Charenton-le-Pont (FR); Francis Maury, Toulouse Cedex 04 (FR); Virginie Santucci, Charenton-le-Pont (FR); François Senocq, Toulouse Cedex 04 (FR); Sylvie Vinsonneau, Charenton-le-Pont (FR)

(73) Assignees: CENTRE NATIONAL DE LA RECHERCHE SCIENTIFI, Paris (FR); ESSILOR INTERNATIONAL (Compagnie Generale d'Optique, Charenton-Le-Pont (FR)

(21) Appl. No.: 13/496,304

(22) PCT Filed: Sep. 6, 2010
(86) PCT No.: PCT/FR10/51849

§ 371 Date: Mar. 15, 2012

(30) Foreign Application Priority Data
Sep. 17, 2009 (FR) 0956386

(51) Int. Cl. C23C 16/02; C23C 16/455

(52) U.S. Cl. 427/562; 118/723 R

(57) ABSTRACT

A method for chemical vapor deposition of a polymer film onto a substrate (6), includes the following two separate, consecutive steps:—a step for the photon activation of the gas phase wherein photon activation energy (42, 43) is provided to at least one gaseous polymer precursor that is present in a mainly gaseous composition, and—a chemical vapor deposition step wherein the activated gaseous polymer precursor, from the photon activation step, is deposited onto a substrate (6) so as to form a polymer film on the substrate, the total gas phase pressure ranging from 10² to 10⁵ Pa. A device (1) for using such a method is also described.

The invention relates to a method of gas-phase chemical deposition, also called chemical vapor deposition (CVD), by which a film of polymer (or polymer film) is deposited by photon activation of a reactive gas phase.

The CVD deposition of polymer films, generally in a thin layer (for example from 50 nanometres to 100 or 200 micrometres), on various substrates is of quite particular interest in the electronics, medical engineering, defence, horology, pharmaceutical, micro- and nanotechnology industries.

Thus, a coating of Parylene®, or poly(p-xylylene), deposited by CVD, has many features that are very attractive for these industries. Deposition takes place in vacuum evaporation at ambient temperature, in the absence of solvent, and results in the production of a semicrystalline transparent film. The method of deposition is known as the Gorham process (Gorham W. F., A new general synthetic method for preparation of linear poly-p-xylylenes, J. Polym. Sci. A-1, 4 (1996) 3027) and is generally implemented by the company COMELEC, in accordance with the teaching of patent EP 1 672 394 B1, of which it is co-proprietor.

Other techniques of chemical vapor deposition have also been investigated without the use of solvents. Thus, the article by K. Chan and K. Gleason, Photoinitiated chemical vapor deposition of polymeric thin films using a volatile photoinitiator, Langmuir 2005, 21, pages 11773-11779, describes the deposition of thin films of polymers, starting from monomers, by a free-radical mechanism. The deposition method, or photo-CVD, is carried out in the dry phase, in a single step, and uses the photolysis of a gaseous photoinitiator in the presence of a gaseous monomer. In this method, the gas phase, the deposit that is forming and the substrate are irradiated simultaneously with photons.

In this article, one example describes a CVD process carried out in the presence of a gaseous monomer, glycidyl methacrylate (GMA), and a gaseous photoinitiator, 2,2′-azobis(2-methylpropane) (ABMP). A film of poly(glycidyl methacrylate) (PGMA) is thus deposited on a silica substrate. Photoinitiation is carried out in a vacuum chamber that contains the substrate, equipped with an external source of UV light, at a wavelength from 350 to 400 nanometres.

However, all the methods described above have the drawback that they are carried out at a very low working pressure. In the case when the polymer film is intended to encapsulate a liquid, this low working pressure limits the nature of the liquids to be encapsulated to those that have a very low vapor pressure at the deposition temperature. The deposition temperature is generally the temperature prevailing in the vicinity of the substrate.

Moreover, one of the drawbacks of these methods of the prior art is that the working pressure is not generally controlled. In fact, the working pressure varies during growth of the polymer film. Another of these drawbacks is that the deposition rate is not constant. That is why the thickness of the deposits is generally difficult to control. Thus, a major drawback of the methods of the prior art is the absence of reproducibility of the deposit of polymer film.

The present patent application aims to overcome the drawbacks of the prior art.

For this purpose, the invention relates to a method of chemical vapor deposition of a polymer film onto a substrate, said method being characterized in that it comprises the following two successive separate steps:
a step of photon activation of the gas phase, in which photon activation energy is supplied to at least one gaseous polymer precursor present in a mainly gaseous composition, and
a step of vapor deposition, in which the activated gaseous polymer precursor, resulting from the photon activation step, is deposited on a substrate, so as to form a polymer film on the substrate, the total pressure of the gas phase being within a range from 10² to 10⁵ Pa.

Therefore the photon activation according to the invention is not performed in the vicinity of the substrate. The substrate and the film growing on the substrate are advantageously protected from possible degradation by the photon activation.

Thus, particularly advantageously according to the invention, photon activation allows energy to be supplied selectively so as to decompose the polymer precursors, but without disturbing the substrate and the gas phase in the vicinity of the substrate.

Another advantage of the invention is that the method is particularly reliable and suitable for industrial application.

Furthermore, a very large variety of polymer films can be deposited on substrates by the method of the invention.

The radiation for photon activation is generally ultraviolet (UV) radiation, most often at a wavelength from 200 to 400 nm.

The substrate is generally solid and of silica, glass, quartz, polymer, or metal. The substrate can even be photosensitive since, in the method of the invention, the substrate is not irradiated by the radiation for photon activation.

The substrate can also comprise at least one cavity in which liquid can be deposited, which is generally a microcell. Said microcell comprises at least one wall, most often of polymer (organic, inorganic or hybrid, i.e. inorganic/organic blend), silica, glass or quartz, preferably of polymer. This polymer is also called resin.

In a particularly preferred embodiment of the invention, the polymer film at least partially covers the liquid deposited on the substrate and preferably at least partly the substrate adjacent to said liquid.

This is the case in particular when the polymer film is deposited on a substrate having at least one microcell in which at least one liquid is deposited.

The liquid deposited on the substrate, which is thus covered at least partially by the polymer film, generally has an inert character with respect to the substrate and especially with respect to the polymer, under the conditions of application of the method of the invention.

Thus, the method according to the invention makes it possible to encapsulate a liquid that is present initially on the substrate, i.e. to envelop said liquid completely by a polymer film and by a portion of the substrate. Most often, the liquid is enclosed in an envelope constituted by a portion of the polymer film and a portion of the substrate. This envelope may or may not be impervious.

In particular, the substrate can be formed from a plurality of microcells, each microcell having at least one wall in common with another microcell, and the film deposited according to the invention can be impervious and can seal all of the microcells in which there is at least one liquid, or only at least two microcells. It is also possible that the film deposited according to the invention is not impervious, and the liquids of the various microcells can mix with one another.

Advantageously, the method according to the invention, in which photon activation is not performed in the vicinity of the substrate, makes it possible to deposit polymer film on a liquid having a low liquid saturated vapor pressure at the deposition temperature.

Preferably, according to the invention, said liquid has a saturated vapor pressure below 100 Pa, preferably below 10 Pa, at the deposition temperature.

Moreover, this saturated vapor pressure is generally lower than the total pressure of the gas phase by a certain ratio, for example from 10 to 100.

Patent EP 1 672 394 B1 mentions a total pressure in the deposition chamber of 7 Pa at the deposition temperature, and states that the saturated vapor pressure of the liquid to be encapsulated must be less than this pressure, and ideally below 0.7 Pa at the deposition temperature. According to the invention, the working pressure can therefore be, in particular and advantageously, greater than the working pressure of the method of deposition of Parylene according to the prior art.

Thus, the method according to the invention can advantageously be applied at a deposition pressure close to atmospheric pressure and/or at a temperature close to ambient temperature (about 20° C.).

In particular, the method according to the invention is such that the temperature of the gas phase is in a range from 20 to 100° C., preferably from 50 to 70° C., in the photon activation step. Moreover, independently or not, the method according to the invention is such that, in the vapor deposition step, the total pressure of the gas phase is preferably in a range from 10² to 4.10³ Pa, and the temperature of the substrate is in a range from −10 to 50° C., preferably from 20 to 30° C.

The polymer precursor is generally a monomer that is photopolymerizable at the wavelength of UV activation, and it can generally be used with or without polymerization photoinitiator. According to the invention, the precursor is preferably selected from the group consisting of the monomers: acrylic derivatives (such as epoxy acrylates, urethane acrylates, polyester acrylates), methacrylic derivatives, Parylene derivatives, styrene derivatives, itaconic derivatives, fumaric derivatives, vinyl halides, vinyl esters, vinyl ethers, and heteroaromatic vinyls; and even more preferably is selected from the group consisting of poly(ethylene glycol) diacrylate (PEGDA), poly(ethylene glycol) methacrylate (PEGMA), 2-hydroxyethyl methacrylate (HEMA), acrylic acid (AA), ethyl acrylate (EA), methyl methacrylate (MMA) and dichloro-di-p-xylylene (dichloro[2,2]paracyclophane). However, it can also be a mixture, for example of thiol and polyene, or a multifunctional monomer such as a di- or tri-acrylate such as 1,6-hexanediol diacrylate (HDDA) or pentaerythritol triacrylate (PETA), or diene such as divinylbenzene or butadiene or isoprene.

Of course, any other polymer precursor that a person skilled in the art might envisage is also comprised within the scope of the invention.

According to the invention, the polymer precursor can be in gaseous form, in which case it supplies directly, alone or in a gas mixture, the photon activation step.

However, said polymer precursor can also be in liquid or solid form, in which case the method of the invention comprises at least one additional step, intended for supplying the polymer precursor, alone or in a mixture, in gaseous form for the photon activation step.

Thus, the method according to the invention can further comprise at least one step of vaporization, of bubbling or of sublimation, which provides feed with gaseous polymer precursor.

The polymer precursor can be in liquid form when it is either in liquid form, or dissolved in a solvent that is itself liquid.

According to the invention, when the polymer precursor is in liquid form, the method further comprises, preferably, at least one vaporization step, said vaporization step being carried out prior to the photon activation step, and providing feed with gaseous polymer precursor.

Said vaporization step can optionally be preceded by a step of liquid injection, for injection of liquid polymer precursor.

Thus, according to an embodiment of the invention, when the polymer precursor is in liquid form, the method can further comprise, preferably, at least one step of liquid injection followed by a vaporization step, said steps of liquid injection and of vaporization being carried out prior to the photon activation step, and said vaporization step providing feed of gaseous polymer precursor.

The step of liquid injection can be a step of pulsed liquid injection.

According to an embodiment of the invention, when the polymer precursor is in liquid form, the method can further comprise at least one bubbling step, said bubbling step being performed by passing at least one carrier gas through liquid polymer precursor prior to the photon activation step, with said bubbling step providing feed of gaseous polymer precursor.

In another embodiment of the invention, when the polymer precursor is in solid form, the method further comprises at least one sublimation step, which provides feed of gaseous polymer precursor. Said sublimation step is carried out prior to the photon activation step.

The method according to the invention therefore permits, advantageously, feed of gaseous polymer precursor starting from a gaseous, liquid or solid compound. The polymer precursor ready for undergoing photon activation is generally in gaseous form.

In all cases, the composition, which is mainly gaseous, preferably completely gaseous, can comprise another compound in addition to the polymer precursor. This other compound, which is for example a photoinitiator, can be supplied at the same time and in the same phase as the polymer precursor supplying the photon activation step.

This other compound is most often selected from the group consisting of solvents of the polymer precursor, photoinitiators and carrier gases.

Thus, the invention also relates to the case when the gaseous composition comprises, besides the polymer precursor, at least one element selected from the group consisting of solvents of the polymer precursor, photoinitiators and carrier gases.

Among the carrier gases, inert or not, nitrogen may be mentioned.

The photoinitiator is generally a compound that can be activated by UV radiation at the chosen wavelength, and can form reactive radicals for initiating the polymerization reaction. The photoinitiator can be selected, for example, from the family of benzyl ketals, benzoins, aromatic α-amino ketones, oxides of acylphosphines, α-hydroxyketones, and phenylglyoxylates. The photoinitiator is especially preferably selected from the following compounds: 1-hydroxy-cyclohexyl-phenyl-ketone (IRGACURE® 184 marketed by the company CIBA) and 2-hydroxy-2-methyl-1-phenyl-1-propanone (DAROCUR® 1173 marketed by the company CIBA).

In a preferred variant of the invention, the step of vapor deposition is carried out in such a way that the gaseous polymer precursor, alone or in a mixture, arrives on the substrate in a flow of gas phase perpendicular to the surface of the substrate.

Advantageously, this provides better control of the thickness of the polymer film as well as the reproducibility of said deposition.

Especially preferably, the substrate additionally moves in a direction perpendicular to said flow of gas phase, which provides continuous deposition of a large area of polymer film, and provides better control of deposition.

Moreover, especially preferably, the substrate additionally rotates in a plane perpendicular to said flow of gas phase, which provides continuous deposition of a large area of polymer film, providing better control of deposition.

The liquid partially covered by the polymer film deposited according to the method of the invention is for example selected from the group consisting of oils, organic solvents with high or low boiling point, liquids containing at least one dye sensitive to temperature and to UV, preferably a dye sensitive to UV, for example a photochromic dye.

The invention also relates to a device that is useful quite particularly for application of the method as described above.

According to the invention, said device is a device for chemical vapor deposition having at least one photon activation chamber, at least one vapor deposition chamber, at least one means for feed of reagent to the photon activation chamber, the device being such that the two chambers are separate and such that it comprises at least one means for circulating gas from the photon activation chamber to the vapor deposition chamber, said device being characterized in that the means for reagent feed is a liquid injection means.

The means for circulating gas from the photon activation chamber to the vapor deposition chamber can be a duct (or pipe). This duct can be heatable, i.e. associated with at least one heating means.

The photon activation chamber is heatable. This can provide temperature control of the compounds present in said chamber.

The vapor deposition chamber is capable of being heated or cooled. This can provide temperature control of the compounds present in said chambers.

Preferably, said device further comprises a mixing chamber located upstream of the activation chamber, in the direction of gas circulation, said mixing chamber being connected to at least one means for feed of reagent to the mixing chamber and at least one means for feed of carrier gas, said mixing chamber moreover being able to mix at least one gas and at least one reagent. The presence of at least two separate means for feed advantageously makes it possible to adjust the proportions and the total flow rate of the species present in the mixing chamber.

In the case when the means for reagent feed is in the mixing chamber, it is not generally present in the photon activation chamber. The means for feed of reagent into the mixing chamber is then the means for reagent feed of the photon activation chamber.

The mixing chamber is heatable. This can provide temperature control of the compounds present in this chamber.

The means for reagent feed, whether it supplies the mixing chamber or the photon activation chamber, is a means for pulsed or non-pulsed liquid injection, preferably a means for pulsed liquid injection. Moreover, independently or not, the means for liquid injection can be associated with a vaporization means. However, the means for reagent feed can also be a simple feed pipe, for example of liquid, associated with said vaporization means.

The means for reagent feed can also be a means for gaseous feed.

Preferably, the means for gaseous feed is supplied by at least one means for vaporization, bubbling or sublimation. For example a means for sublimation can supply the means for gaseous feed, which is a simple duct, heated or not, opening into the photon activation chamber or the mixing chamber.

Thus, according to the invention, the device can further comprise at least one of the vaporization means, the bubbling means and the sublimation means, and preferably the device further comprises a vaporization means.

In particular, according to the invention, the device further comprises at least one means for controlling the total pressure in the deposition chamber.

Advantageously, this provides homogeneity of the structure and properties of the deposit.

The invention will be better understood on examining the following drawings, where:

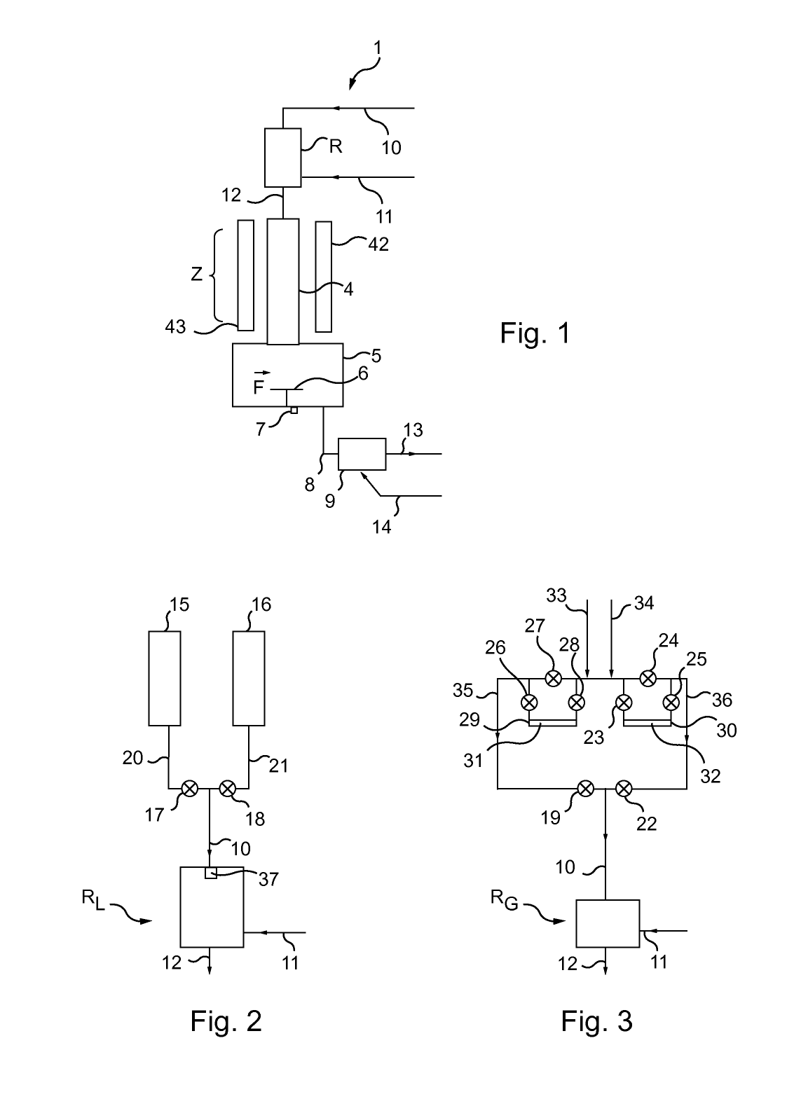

FIG. 1 is a schematic representation of a device according to the invention having a mixing chamber R;

FIG. 2 is a schematic representation of chamber R, in the case when the polymer precursor is liquid and chamber R is a mixing and vaporizing chamber R_{L}, as well as the feed device upstream of said chamber R_{L}; and

FIG. 3 is a schematic representation of chamber R, here R_{G}, in the case when the polymer precursor is gaseous, and of the feed device upstream of said chamber R_{G}.

Two variants of the device according to the invention are shown in FIGS. 1 to 3, according to whether the polymer precursor is liquid (combination of FIGS. 1 and 2, first variant) or gaseous (combination of FIGS. 1 and 3, second variant).

The device 1 comprises a pipe 10 for supplying species, in particular reagents, a pipe 11 for supplying at least one carrier gas, for example such as nitrogen N₂, these two pipes 10 and 11 supplying a mixing chamber R. The carrier gas is an inert carrier gas, and advantageously permits adjustment of the dilution and total flow rate of the gas phase passing through the UV activation zone.

A pipe 12 leaving chamber R provides feed to a UV activation zone Z. Zone Z comprises four lamps, of which two UV lamps 42 and 43 are shown in FIG. 1, intended for activating any reactive compound (with UV radiation at the wavelength used) passing through a chamber 4 located within zone Z. Chamber 4 is the photon activation chamber according to the invention. Chamber 4 is constituted by a quartz tube. The four lamps in zone Z generally operate at 250 nanometres. However, some other number of lamps and some other value of wavelength can also be selected by a person skilled in the art.

Chamber 4 is supplied with the species, in particular reagents, leaving chamber R, via pipe 12.

Gas is circulated by a gas circulating means (not shown), which is for example a pipe, from chamber 4 to a deposition chamber 5, which is the vapor deposition chamber of the invention.

As shown in FIG. 1, chamber 5 is located downstream of and vertically beneath chamber 4.

A substrate 6, generally in the form of a plate, is put in the deposition chamber 5, in such a way that the gaseous flow of matter, in particular activated by UV, which comes from chamber 4 arrives perpendicularly to the plane of the substrate 6. An arrow F indicates one possibility for translational movement of substrate 6 in such a way that the polymer film is deposited as regularly as possible and on an area of substrate 6 that is as extensive as possible.

An air reset valve 7 is associated with the deposition chamber 5. A pipe 8 enables a pressure regulating chamber 9 to be supplied from chamber 5. Chamber 9 is supplied via a pumping line 14 and its outlet is connected to a pressure control pipe 13, which allows the surplus gas to be discharged.

The assembly (8, 9, 13, 14) constitutes a means for controlling the total pressure in chamber 5, in the form of a pumping system with automatic pressure control.

Advantageously, according to the invention, device 1 makes it possible to produce thin films of polymers, in particular at a pressure close to 1 torr (or 100 Pa), and with means for activation of the gas phase and only of the gas phase.

FIG. 2 is a schematic representation of the mixing and vaporizing chamber R_{L}, in the case when the polymer precursor is liquid, as well as the feed device upstream of said chamber R_{L}, in the context of the first variant of the device according to the invention combining FIGS. 1 and 2.

Relative to chamber R, chamber R_{L} comprises at least one means for vaporization (not shown), generally constituted by at least one heating means.

Pipe 10 opens into a system for pulsed liquid injection 37.

In the case shown in FIG. 2, the liquid to be supplied to chamber R_{L} comprises either a cleaning solvent or a monomer (which is the reagent). In fact, a pressurized solvent reservoir 15 and a pressurized reservoir 16 of monomer that is liquid (or in solution) can feed, respectively via a pipe 20 regulated by a valve 17 and via a pipe 21 regulated by a valve 18, a pipe 10. Pipe 10 opens into the injector 37 feeding the mixing and vaporizing chamber R_{L}. Chamber R_{L} supplies, via pipe 12, a gas flow supplying chamber 4. Said gas flow comprises the reagent in the gaseous state.

According to the invention, injector 37 is preferably cleaned with a suitable liquid product, such as the cleaning solvent, after each test. FIG. 3 is a schematic representation of the mixing chamber R_{G}, in the case when the polymer precursor is gaseous, and the feed device upstream of said chamber R_{G}, in the context of the second variant of the device according to the invention combining FIGS. 1 and 3.

The means for reagent feed is pipe 10, which is supplied by a sublimation means (23, 24, 25, 26, 27, 28). The gaseous composition consisting of the reagent generally includes other species such as solvent or solvents, one or more carrier gases, one or more photoinitiators. In the case shown in FIG. 3, the feed gas flow comprises a photoinitiator, a carrier gas and a monomer.

In FIG. 3, a reservoir 29 of solid photoinitiator 31, regulated by valves 26, 27, and 28, and a pipe 33 for feed of carrier gas respectively supply a mixing pipe 10 with carrier gas and sublimed photoinitiator, via a pipe 35, regulated by a valve 19.

In the same way, a reservoir 30 of solid monomer 32, regulated by valves 23, 24, and 25, and a pipe 34 for feed of carrier gas respectively supply mixing pipe 10 with carrier gas and with sublimed monomer, via a pipe 36, regulated by a valve 22.

Pipe 10 opens into the mixing chamber R_{G}. The gaseous composition leaving said chamber R_{G} via pipe 12 comprises the monomeric reagent, the carrier gas and the photoinitiator in the gaseous state.

In general, a person skilled in the art is capable of adapting the device according to the invention, as represented by the two variants in FIGS. 1 to 3, while remaining within the scope of the invention.

The examples given below illustrate the invention without limiting its scope.

### EXAMPLES

The invention was implemented according to the illustrative, non limitative examples, by the first variant of the device according to the invention shown in FIGS. 1 and 2.

In the context of these examples, the reactive product or products were liquid. They were placed initially in reservoir 16. Pressure was applied to propel them by pipe 10 to the pulsed injector 37. This injector 37 generated a spray, which was then vaporized completely in the vaporizing and mixing chamber R_{L}.

The gaseous reactive species entering chamber R_{L} were mixed by the introduction of carrier gas N₂ via pipe 11 and were vaporized by a system for heating said chamber R_{L}, at a temperature generally from 40 to 80° C.

The reactive vapors were then entrained by the carrier gas into pipe 12 and then into the quartz tube 4 that is transparent to the radiation used, where they underwent photon activation at 254 nm, by the four lamps (42, 43) arranged around the chamber 4.

The vapors activated by the radiation were then conveyed into the deposition chamber 5 where they condensed and polymerized on the substrate 6 placed at the centre of chamber 5. The deposition chamber 5 was left at ambient temperature (about 20° C.).

The device 1 was equipped with a pumping system and automatic pressure control (8, 9, 13, 14). The unreacted reactive vapors were trapped in a liquid nitrogen trap (not shown in FIG. 1) located at the outlet of deposition chamber 5.

According to these examples, the method of deposition according to the invention was applied successfully for several cases.

1. The polymer deposited was poly(acrylic acid) (PAA). It was produced starting from the liquid monomer: acrylic acid (vapor pressure: 5.33 torr or 711 Pa at 20° C., viscosity 1.3 cP at 25° C.) and without addition of photoinitiator. The silicon substrate was at ambient temperature and the deposition pressure was 20 torr (2667 Pa), the flow rate of carrier gas (N₂) being 500 sccm (or 0.845 Pa.m³.s⁻¹).

2. The polymer deposited was poly(methyl methacrylate) (PMMA). It was deposited starting from the liquid monomer: methyl methacrylate (vapor pressure: 38.7 torr (5147 Pa) at 20° C., viscosity 0.7 cP at 25° C.) and a photoinitiator: IRGACURE®184, dissolved in the monomer (2 wt. %). The silicon and glass substrates were at ambient temperature and the deposition pressure was 6 torr (800 Pa). The flow rate of carrier gas (N₂) was 250 sccm (or 0.422 Pa.m³.s⁻¹). The two films obtained on these two substrates were transparent, with an average thickness of 400 nm.

3. Hexadecane was encapsulated with poly(hydroxyethyl methacrylate) (PHEMA). Hexadecane does not dissolve poly(hydroxyethyl methacrylate) or its monomer. Hexadecane was encapsulated successfully under the conditions described in example 2 of deposition with PMMA.

Hexadecane is a liquid that is too volatile (vapor pressure of 0.01 torr, or 1.33 Pa, at 40° C.) to be encapsulated by COMELEC's Parylene method (where the operating pressure is 3.7 mtorr or 0.5 Pa at 40° C.).

CVD deposition according to the invention therefore made it possible to produce a PHEMA film encapsulating hexadecane, which is novel. As a result there is considerable interest in the method and device according to the invention.

1. Method of chemical vapor deposition of a polymer film onto a substrate (6), said method being characterized in that it comprises the following two separate successive steps:
a step of photon activation of the gas phase in which photon activation energy (42, 43) is supplied to at least one gaseous polymer precursor present in a mainly gaseous composition, and
a step of vapor deposition in which the activated gaseous polymer precursor, resulting from the photon activation step, is deposited on a substrate (6) so as to form a polymer film on the substrate, the total pressure of the gas phase being within a range from 10² to 10⁵ Pa.

2. Method according to claim 1, wherein the temperature of the gas phase is in a range from 20 to 100° C., preferably from 50 to 70° C., in the photon activation step, and/or such that, in the vapor deposition step, the temperature of the substrate is in a range from −10 to 50° C., preferably from 20 to 30° C.

3. Method according to claim 1, wherein the total pressure of the gas phase is in a range from 10² to 4.10³ Pa.

4. Method according to claim 1, wherein the polymer film deposited covers at least partially the liquid deposited on the substrate and preferably at least partly the substrate adjoining said liquid.

5. Method according to claim 4, wherein said liquid has a saturated vapor pressure below 100 Pa, preferably below 10 Pa, at the deposition temperature.

6. Method according to claim 1, wherein the polymer precursor is selected from the group consisting of the monomers: acrylic derivatives (such as epoxy acrylates, urethane acrylates, polyester acrylates), methacrylic derivatives, Parylene derivatives, styrene derivatives, itaconic derivatives, fumaric derivatives, vinyl halides, vinyl esters, vinyl ethers, and heteroaromatic vinyls; and is preferably selected from the group consisting of poly(ethylene glycol) diacrylate (PEGDA), poly(ethylene glycol) methacrylate (PEGMA), 2-hydroxyethyl methacrylate (HEMA), acrylic acid (AA), ethyl acrylate (EA), methyl methacrylate (MMA) and dichloro-di-p-xylylene (dichloro[2,2]paracyclophane).

7. Method according to claim 1, further comprising, when the polymer precursor is in liquid form, at least one vaporization step, said vaporization step being carried out prior to the photon activation step, and permitting feed with gaseous polymer precursor, said vaporization step being optionally preceded by a step of liquid injection, which permits injection of the liquid polymer precursor.

8. Method according to claim 1, further comprising least one step of vaporization, of bubbling or of sublimation (23, 24, 25, 26, 27, 28), which provides feed with gaseous polymer precursor.

9. Method according to claim 1, wherein the step of vapor deposition is carried out in such a way that the gaseous polymer precursor, alone or in a mixture, arrives on the substrate in a flow of gas phase perpendicular to the surface of the substrate.

10. Method according to claim 1, wherein the gaseous composition comprises, besides the polymer precursor, at least one element selected from the group consisting of solvents of the polymer precursor, photoinitiators and carrier gases.

11. Device (1) for chemical vapor deposition comprising at least one photon activation chamber (4), at least one vapor deposition chamber (5), at least one means for reagent feed (12) of the photon activation chamber (4), said device (1) being such that the two chambers (4, 5) are separate and such that it comprises at least one means for circulation of gas from the photon activation chamber (4) to the vapor deposition chamber (5), said device (1) being characterized in that the means for reagent feed is a means for liquid injection.

12. Device (1) for chemical vapor deposition according to claim 11 further comprising a mixing chamber (R, R_{G}, R_{L}) located upstream of the activation chamber (4), in the direction of gas circulation, said mixing chamber (R, R_{G}, R_{L}) being connected to at least one means for reagent feed (10, 37; 10) of the mixing chamber (R, R_{G}, R_{L}) and at least one means for feed (11) of carrier gas, said mixing chamber (R, R_{G}, R_{L}) moreover being able to mix at least one gas and at least one reagent.

13. Device (1) for chemical vapor deposition according to claim 11, wherein the means for reagent feed (12; 10, 37; 10) is associated with a vaporizing means.

14. Device (1) for chemical vapor deposition according to claim 11, wherein the means for reagent feed is a means for pulsed liquid injection (37).

15. Device (1) for chemical vapor deposition according to claim 11, further comprising at least one means for regulation (8, 9, 13, 14) of the total pressure in the deposition chamber (5).
